(19) United States
(12) Patent Application Publication
(10) Pub. No.: US 2026/0271310 A1
(43) Pub. Date: Sep. 10, 2026

(54) SEMICONDUCTOR DEVICES SUPPORTING HIGH MEMORY DENSITY, AND ASSOCIATED SYSTEMS AND METHODS

(71) Applicant: Micron Technology, Inc., Boise, ID (US)

(72) Inventor: Yeon Seung Jung, Hwaseong (KR)

(21) Appl. No.: 19/456,985

(22) Filed: Jan. 22, 2026

Related U.S. Application Data
(60) Provisional application No. 63/768,514, filed on Mar. 7, 2025.

(51) Int. Cl. H10B 80/00; H10W 90/00; H10W 90/10

(52) U.S. Cl. CPC H10B 80/00; H10W 90/10; H10W 90/724

(57) ABSTRACT

System-in-package (SiP) devices with high memory density are disclosed herein. In some embodiments, a SiP device includes a substrate, a connection layer, a host device, a first HBM device, and a second HBM device. The substrate can be positioned at a first level. The connection layer can be carried by the substrate. The host device can be carried by the connection layer and positioned at a second level different from the first level. The first HBM device can be carried by the connection layer and positioned at the second level. The second HBM device can be coupled to the connection layer and positioned at the first level.

### CROSS-REFERENCE TO RELATED APPLICATIONS

The present application claims priority to U.S. Provisional Patent Application No. 63/768,514, filed Mar. 7, 2025, the disclosure of which is incorporated herein by reference in its entirety.

### TECHNICAL FIELD

The present technology generally relates to semiconductor devices, and more particularly relates to semiconductor devices supporting high memory density.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are "packaged" to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

Features, aspects, and advantages of the presently disclosed technology may be better understood with regard to the following drawings.

FIGS. 1A and 1B are schematic cross-sectional and plan views, respectively, of a system-in-package (SiP) device.

FIGS. 2A and 2B are schematic cross-sectional and plan views, respectively, of a SiP device configured in accordance with embodiments of the present technology.

FIG. 3 is a plan view of a substrate included in the SiP device of FIGS. 2A and 2B, and configured in accordance with embodiments of the present technology.

FIG. 4 is a schematic cross-sectional view of another SiP device configured in accordance with embodiments of the present technology.

FIG. 5 is a schematic cross-sectional view of another SiP device configured in accordance with embodiments of the present technology.

FIGS. 6A–6C are schematic plan and two cross-sectional views of another SiP device configured in accordance with embodiments of the present technology.

FIG. 7 is a schematic plan view of another SiP device configured in accordance with embodiments of the present technology.

FIG. 8 is a schematic plan view of another SiP device configured in accordance with embodiments of the present technology.

FIGS. 9A–9H illustrate a process flow for packaging a SiP device in accordance with embodiments of the present technology.

FIG. 10 is a flowchart illustrating a method for packaging a SiP device in accordance with embodiments of the present technology.

A person skilled in the relevant art will understand that the features shown in the drawings are for purposes of illustrations, and variations, including different and/or additional features and arrangements thereof, are possible.

### DETAILED DESCRIPTION

### Overview

Embodiments of the present technology are directed to semiconductor devices supporting high memory density. As artificial intelligence and other forms of computing with high processing demand become more prevalent, the demand for more memory is expected to continue to increase. However, increasing the total memory available can be challenging due to size constraints. For example, semiconductor devices may have height restrictions that effectively limit how many memory dies can be stacked in the vertical direction. As another example, distributing more memory dies across the device in the lateral direction not only takes up valuable real estate, but can also reduce the effective core area of any host device (e.g., CPU, GPU) packaged alongside the memory dies.

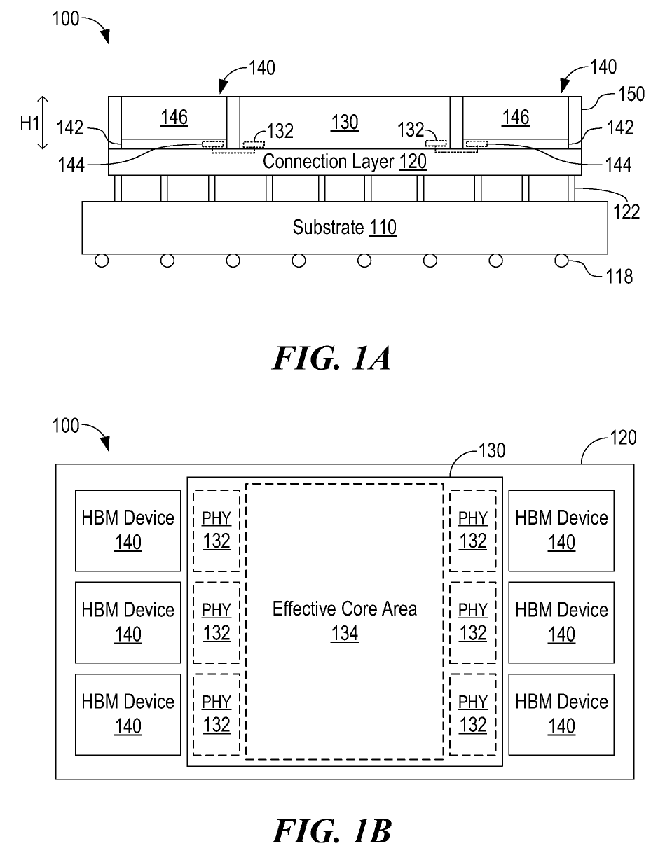

To illustrate, FIGS. 1A and 1B are schematic cross-sectional and plan views, respectively, of a system-in-package (SiP) device 100. Referring first to FIG. 1A, the SiP device 100 includes a substrate 110, a connection layer 120, a host device 130, one or more High-Bandwidth Memory (HBM) devices 140, and an encapsulant 150. A first side (e.g., a bottom side) of the substrate 110 can be coupled to other system components (not shown) via a plurality of first interconnect structures 118. The connection layer 120 can be a redistribution layer (RDL), a silicon interposer, and/or the like. The connection layer 120 can be coupled to a second side (e.g., an upper side) of the substrate 110 via a plurality of second interconnect structures 122. The first interconnect structures 118 and the second interconnect structures 122 can be solder structures (e.g., solder balls), metal-metal bonds, bumps, micro bumps, and/or any other suitable conductive structures that mechanically and electrically couple the respective two components.

Each of the host device 130 and the one or more HBM devices 140 (two are shown in FIG. 1A) can be carried by the connection layer 120, and the encapsulant 150 can at least partially encapsulate the host device 130 and the HBM devices 140. The host device 130 can include a variety of components, such as a processing unit (e.g., CPU/GPU/TCU), one or more registers, one or more cache memories, and/or a variety of other components (not shown). Each of the HBM devices 140 can include a base die 142 (e.g., a logic die, an interface die) carried by the connection layer 120 and a plurality of memory dies 146 (schematically illustrated as a single block) stacked on and carried by the base die 142. The SiP device 100 can be associated with a particular memory density (e.g., the number of memory dies 146 per SiP device 100).

As further shown in FIG. 1A, the host device 130 can include one or more physical layer (PHY) areas 132, and each base die 142 can include a corresponding PHY area 144. The host device 130 can include the same number of PHY areas 132 as the number of HBM devices 140, and each PHY area 132 of the host device 130 can be communicatively coupled to the PHY area 144 of a corresponding HBM device 140. For example, each of the PHY areas 132, 144 can include I/O circuits that enable signal transmission (e.g., through the connection layer 120) between the host device 130 and each of the one or more HBM devices 140.

It can be difficult to increase the memory density of the SiP device 100 by stacking additional memory dies 146 on top within each HBM device 140. In many cases, the height of the SiP device 100 above the connection layer 120, corresponding to the height of each HBM device 140, is limited to a height cap H1 due to various mechanical, thermal, and/or other constraints. For example, the height cap H1 can be between about 750–800 µm (e.g., 775 µm). Also, because each of the memory dies 146 has a minimum thickness, the cap height H1 effectively limits how many memory dies 146 can be included in each HBM device 140. Therefore, it may be unfeasible to simply stack additional memory dies 146.

It can also be difficult to increase the memory density of the SiP device 100 by including additional HBM devices 140 carried by the connection layer 120. As shown in FIG. 1B, the HBM devices 140 are positioned lateral and adjacent to the host device 130 and/or one another. More specifically, three HBM devices 140 are arranged along each of the left and right sides of the host device 130, for a total of six HBM devices 140. Including additional HBM devices 140 would require additional real estate on the connection layer 120 and/or the substrate 110, which may be costly or impractical due to various constraints. Moreover, the host device 130 includes the same number of PHY areas 132 as the number of HBM devices 140. A greater number of PHY areas 132 inherently reduces the effective core area 134 of the host device 130, which in turn can decrease the processing power thereof. Therefore, it may be undesirable to simply include more HBM devices 140 on the connection layer 120.

Embodiments of the present technology address at least some of the above described issues for increasing the memory density of SiP devices. For example, embodiments of the present technology include HBM devices at a same level as the substrate. In some embodiments, a SiP device includes a substrate, a connection layer, a host device, a first HBM device, and a second HBM device. The substrate can be positioned at a first level. The connection layer can be carried by the substrate. The host device can be carried by the connection layer and positioned at a second level different from the first level. The first HBM device can be carried by the connection layer and positioned at the second level. The second HBM device can be coupled to the connection layer and positioned at the first level.

In some embodiments, a method for packaging a SiP device includes providing an assembly including a host device, a first HBM device, a connection layer, and a plurality of interconnect structures. The connection layer can have a first side coupled to each of the host device and the first HBM device. The plurality of interconnect structures can be coupled to a second side of the connection layer. The method can also include forming a second HBM device on a first subset of the plurality of interconnect structures. The method can further include coupling a substrate to a second subset of the plurality of interconnect structures. The substrate can be positioned at a same level as the second HBM device.

In some embodiments, a SiP device includes a substrate, a connection layer, a host device, a first HBM device, and a second HBM device. The connection layer can have a first side and a second side opposite the first side, and the second side of the connection layer can be coupled to the substrate. The host device can be coupled to the first side of the connection layer. The first HBM device can be coupled to the first side of the connection layer. The second HBM device can be coupled to the second side of the connection layer.

Embodiments of the present technology enable a greater number of HBM devices to be included in the SiP device (and thus a higher memory density) without exceeding the height cap H1, while occupying the same amount of or less real estate, and while a larger or the same effective core area for the host devices. Moreover, SiP devices configured in accordance with embodiments of the present technology can be manufactured and packaged using existing assembly equipment and technology. Furthermore, SiP devices configured in accordance with embodiments of the present technology are compatible with existing systems and do not require adapters and/or the like.

In the Figures, identical reference numbers identify generally similar, and/or identical, elements. Many of the details, dimensions, and other features shown in the Figures are merely illustrative of particular embodiments of the disclosed technology. Accordingly, other embodiments can have other details, dimensions, and features without departing from the spirit or scope of the disclosure. In addition, those of ordinary skill in the art will appreciate that further embodiments of the various disclosed technologies can be practiced without several of the details described below.

### Select Embodiments of SiP Devices

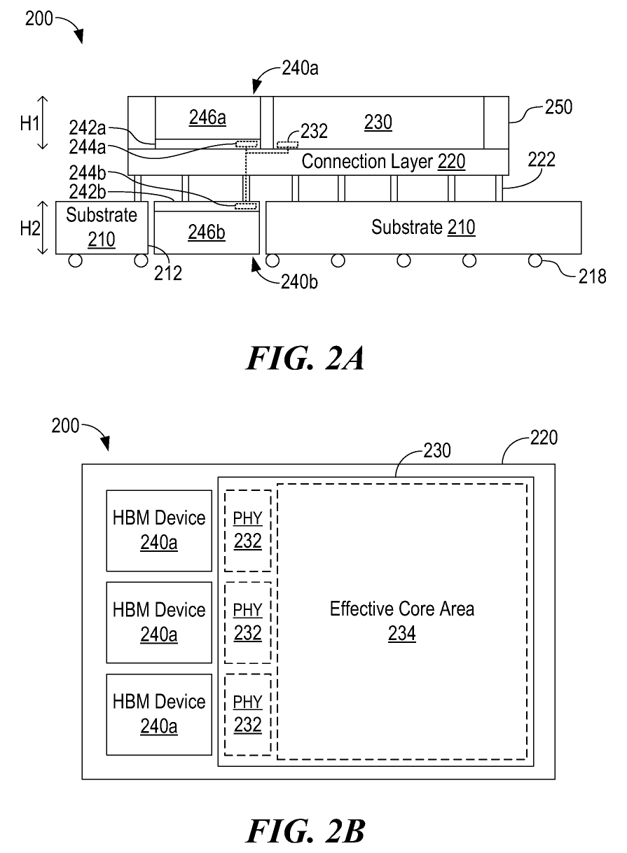

FIGS. 2A and 2B are schematic cross-sectional and plan views, respectively, of a SiP device 200 configured in accordance with embodiments of the present technology. Referring first to FIG. 2A, the SiP device 200 can include a substrate 210, a connection layer 220, a host device 230, one or more first HBM devices 240a, and an encapsulant 250. A first side (e.g., a bottom side) of the substrate 210 can be coupled to other system components (not shown) via a plurality of first interconnect structures 218. The connection layer 220 can be a redistribution layer (RDL), a silicon interposer, and/or the like. The connection layer 220 can be coupled to a second side (e.g., an upper side) of the substrate 210 via a plurality of second interconnect structures 222. The first interconnect structures 218 and the second interconnect structures 222 can be solder structures (e.g., solder balls), metal-metal bonds, bumps, micro bumps, and/or any other suitable conductive structures that mechanically and electrically couple the respective two components.

Each of the host device 230 and the one or more first HBM devices 240a (one is shown in FIG. 2A) can be carried by the connection layer 220, and the encapsulant 250 can at least partially encapsulate the host device 230 and the first HBM devices 240a. The host device 230 can include a variety of components, such as a processing unit (e.g., CPU/GPU/TCU), one or more registers, one or more cache memories, and/or a variety of other components (not shown). Each of the first HBM devices 240a can include a first base die 242a (e.g., a logic die, an interface die) carried by the connection layer 220 and a plurality of first memory dies 246a (schematically illustrated as a single block) stacked on and carried by the first base die 242a.

As further shown in FIG. 2A, the SiP device 200 can further include one or more second HBM devices 240b positioned at the same level as the substrate 210. In particular, the substrate 210 can include one or more apertures 212 shaped and sized to receive the one or more second HBM devices 240b. Each of the second HBM devices 240b can include a second base die 242b (e.g., a logic die, an interface die) coupled to the second interconnect structures 222 and a plurality of second memory dies 246b (schematically illustrated as a single block) stacked below the second base die 242b. Thus, as shown, each pair of a first HBM device 240a and a second HBM device 240b is in a face-to-face (F2F) arrangement in which their respective base dies 242a, 242b are facing one another.

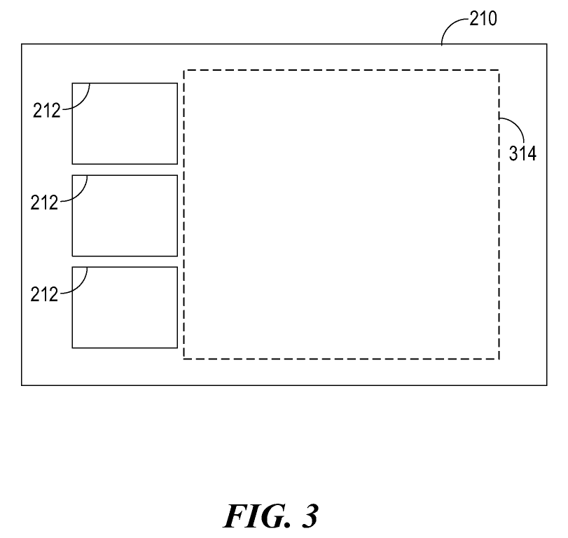

Referring momentarily to FIG. 3, which is a plan view of the substrate 210, in the illustrated embodiment, the substrate 210 includes three apertures 212 shaped and sized to receive corresponding ones of three second HBM devices 240b. FIG. 3 also illustrates (in phantom lines) a host device zone 314 representing the lateral position of the host device 230 when assembled on the substrate 210. Returning to FIG. 2A, the substrate 210 can have a height H2 greater than the height of each second HBM device 240b (not drawn to scale) such that the second HBM devices 240b can be fully laterally surrounded by the substrate 210. For example, the height H2 can be between about 1–3 mm (e.g., 2 mm). In the illustrated embodiment, the apertures 212 are positioned such that the second HBM devices 240b are vertically aligned with (e.g., positioned generally below) corresponding ones of the first HBM devices 240a. Thus, compared to the SiP device 100 of FIGS. 1A and 1B, the SiP device 200 can include additional HBM devices without exceeding the height cap H1.

The host device 230 can include one or more PHY areas 232, each first base die 242a can include a corresponding PHY area 244a, and each second base die 242b can include a corresponding PHY area 244b. Each PHY area 132 of the host device 130 can be communicatively coupled to (i) the PHY area 244a of a corresponding first HBM device 240a via the connection layer 220 and (ii) the PHY area 244b of a corresponding second HBM device 240b via the connection layer 220 and the second interconnect structures 222. For example, each of the PHY areas 232, 244a, 244b can include I/O circuits that enable signal transmission between the host device 230 and each of the first HBM devices 240a and the second HBM devices 240b.

Referring next to FIG. 2B, three first HBM devices 240a are shown positioned along one side of the host device 230. Three second HBM devices 240b (not visible in FIG. 2B) can be positioned underneath corresponding ones of the three first HBM devices 240a. Accordingly, although the SiP device 200 has the same memory density as the SiP device 100 of FIGS. 1A and 1B (six HBM devices per SiP device), only the three first HBM devices 240a are carried by the connection layer 220, resulting in less real estate required or occupied compared to the SiP device 100. Moreover, because each PHY area 232 of the host device 230 is communicatively coupled to two PHY areas (e.g., the PHY area 244a of a corresponding first base die 242a and the PHY area 244b of a corresponding second base die 242b), the host device 230 can require half as many PHY areas compared to the host device 130 of FIGS. 1A and 1B. Having fewer PHY areas 232 can result in a larger effective core area 234 for the host device 230 compared to the host device 130.

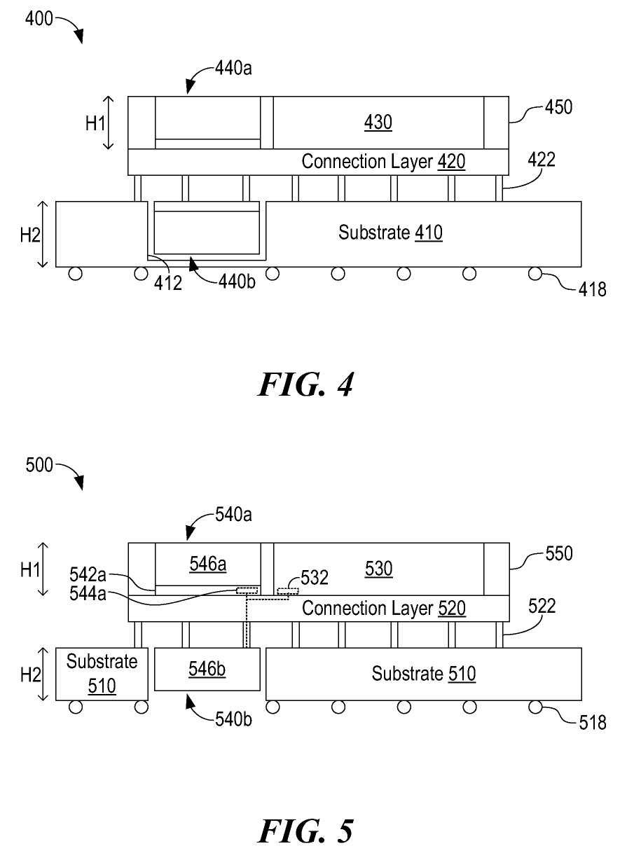

FIG. 4 is a schematic cross-sectional view of another SiP device 400 configured in accordance with embodiments of the present technology. The SiP device 400 can be generally similar to the SiP device 200 of FIGS. 2A and 2B. For example, the SiP device 400 can include a substrate 410, a plurality of first interconnect structures 418, a connection layer 420, a plurality of second interconnect structures 422, a host device 430, one or more first HBM devices 440a, one or more second HBM devices 440b, and an encapsulant 450.

Unlike the substrate 210 of FIG. 2A, however, the substrate 410 can include one or more recesses 412. Each of the recesses 412 can be shaped and sized to receive one or more of the second HBM devices 440b, but does not extend fully through the substrate 410. For example, the height of each second HBM device 440b can be substantially the same as the height of each first HBM device 440a, corresponding to the height cap H1 (e.g., 775 µm), and the height H2 of the substrate 410 can be larger (e.g., 2 mm). Also, in the illustrated embodiment, the recess 412 is positioned such that the second HBM device 440b is vertically aligned with (e.g., positioned generally below) a corresponding first HBM device 440a. Thus, compared to the SiP device 100 of FIGS. 1A and 1B, the SiP device 400 can include additional HBM devices without exceeding the height cap H1, while occupying less real estate, and while leaving a larger effective core area for the host device.

FIG. 5 is a schematic cross-sectional view of another SiP device 500 configured in accordance with embodiments of the present technology. The SiP device 500 can be generally similar to the SiP device 200 of FIGS. 2A and 2B. For example, the SiP device 500 can include a substrate 510, a plurality of first interconnect structures 518, a connection layer 520, a plurality of second interconnect structures 522, a host device 530, one or more first HBM devices 540a, one or more second HBM devices 540b, and an encapsulant 550. The host device 530 can include a PHY area 532. Each first HBM device 540a can include a first base die 542a carried by the connection layer 520 and having a PHY area 544a, and a plurality of first memory dies 546a stacked on and carried by the first base die 542a.

Unlike the second HBM device 240b of FIG. 2A, however, the second HBM device 540b does not include a base die and includes only a plurality of second memory dies 546b. The second memory dies 546b can be coupled to the second interconnect structures 522, and can be communicatively coupled to the PHY areas 532, 544a via the second interconnect structures 522 and the connection layer 520. Because the second HBM device 540b lacks its own base dies for control operations, in some embodiments, the base die 542a of the corresponding first HBM device 540a can serve as the effective base die for the second HBM device 540b and perform control operations. Thus, compared to the SiP device 100 of FIGS. 1A and 1B, the SiP device 500 can include additional HBM devices without exceeding the height cap H1, while occupying less real estate, and while leaving a larger effective core area for the host device.

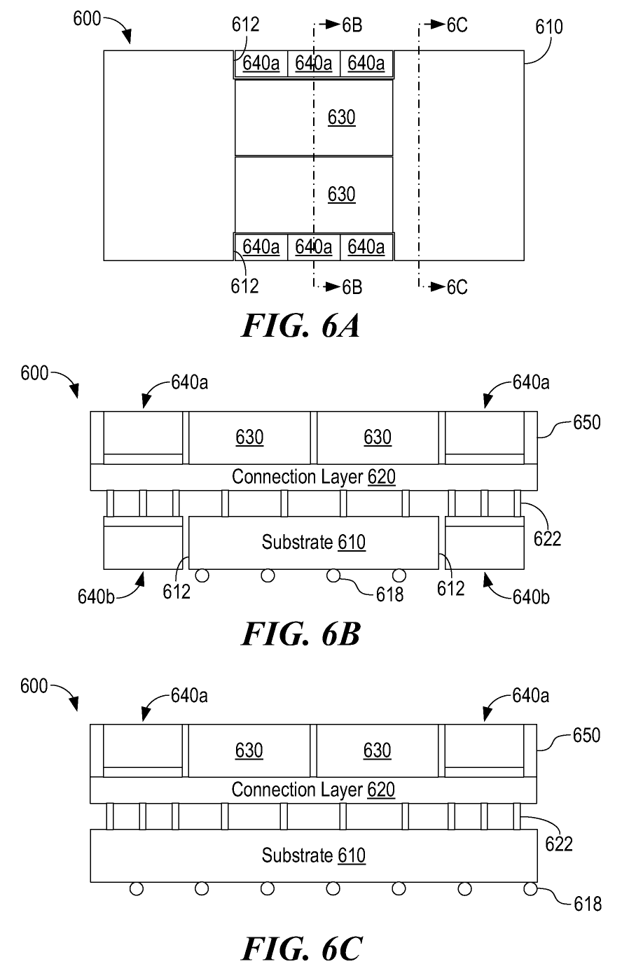

FIGS. 6A–6C are schematic plan and two cross-sectional views of another SiP device 600 configured in accordance with embodiments of the present technology. Referring to FIGS. 6A–6C together, the SiP device 600 can be generally similar to the SiP device 200 of FIGS. 2A and 2B. For example, the SiP device 600 can include a substrate 610, a plurality of first interconnect structures 618, a connection layer 620, a plurality of second interconnect structures 622, one or more host devices 630 (two are included in the illustrated embodiment), one or more first HBM devices 640a (six are included in the illustrated embodiment), one or more second HBM devices 640b (six are included in the illustrated embodiment), and an encapsulant 650.

Unlike the substrate 210 of FIG. 2A, however, the substrate 610 does not include any apertures (or recesses, such as the recess 412 of FIG. 4). Instead, the substrate 610 includes a pair of notches 612, each generally centered along a corresponding one of a pair of opposite sides of the substrate 610. Each of the notches 612 can be shaped and sized to receive one or more of the second HBM devices 640b. For example, referring to FIG. 6A, which omits the connection layer 620 for illustrative purposes only, the substate 610 has a general H-shape such that the pair of host devices 630 are positioned above the bridge of the ‘H’ and the first and second HBM devices 640a, 640b are aligned with the notches 612. The first HBM device 640a can be carried by the connection layer 620. In the illustrated embodiment, three first HBM devices 640a and three second HBM devices 640b are aligned with each notches 612.

FIG. 6B is a cross-sectional (e.g., cutaway) view of the SiP device 600 taken along plane 6B-6B of FIG. 6A. As shown, the second HBM devices 640b are positioned at the edges of the substrate 610 in the respective notches 612 (e.g., as opposed to in apertures or recesses thereof). The second HBM devices 640b are also vertically aligned with corresponding ones of the first HBM devices 640a. FIG. 6C is a cross-sectional (e.g., cutaway) view of the SiP device 600 taken along plane 6C-6C of FIG. 6A. The second HBM devices 640b are obscured behind the substrate 610, and the first HBM devices 640a and the host devices 630 remain visible on the connection layer 620.

Referring to FIGS. 6A–6C together, forming the notches 612 as opposed to forming apertures or recesses can provide several advantages. For example, substrates with notches can be both easier to manufacture and more rigid and resilient against warpage compared to substrates with apertures. As another example, by positioning the second HBM devices 640b along the periphery of the substrate 610, as opposed to in the middle thereof, heat dissipated by the second HBM devices 640b can be better removed and/or otherwise managed.

FIG. 7 is a schematic plan view of another SiP device 700 configured in accordance with embodiments of the present technology. The SiP device 700 can be generally similar to the SiP device 200 of FIGS. 2A and 2B. For example, the SiP device 700 can include a substrate 710, a pair of host devices 730, first HBM devices 740a, and second HBM devices (obscured behind the first HBM devices 740a). The first HBM devices 740a can be stacked lateral to the host devices 730, and the second HBM devices can be positioned underneath corresponding ones of the first HBM devices 740a and at the same level as the substrate 710. Also, while omitted in FIG. 7 for illustrative purposes, the SiP device 700 can further include a plurality of first interconnect structures, a connection layer, a plurality of second interconnect structures, an encapsulant, and/or the like.

In the illustrated embodiment, the substrate 710 has a generally rectangular shape and extends underneath the pair of host devices 730, but does not extend underneath the first HBM devices 740a. The first HBM devices 740a can be carried by the connection layer (not shown), and the second HBM devices can be positioned along the edges of the substrate 710. Compared to the H-shaped substrate 610 of FIG. 6A, the rectangular substrate 710 can be easier to manufacture because the substrate 710 does not include any notches, apertures, recesses, and/or the like.

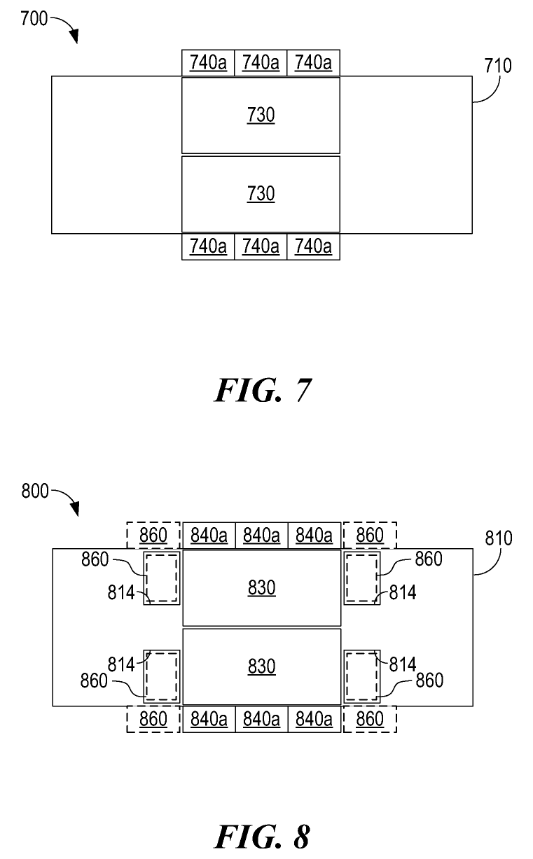

FIG. 8 is a schematic plan view of another SiP device 800 configured in accordance with embodiments of the present technology. The SiP device 800 can be generally similar to the SiP device 200 of FIGS. 2A and 2B. For example, the SiP device 800 can include a substrate 810, a pair of host devices 830, first HBM devices 840a, and second HBM devices (obscured behind the first HBM devices 840a). The first HBM devices 840a can be stacked lateral to the host devices 830, and the second HBM devices can be positioned underneath corresponding ones of the first HBM devices 840a and at the same level as the substrate 810. Also, while omitted in FIG. 8 for illustrative purposes, the SiP device 800 can further include a plurality of first interconnect structures, a connection layer, a plurality of second interconnect structures, an encapsulant, and/or the like. In the illustrated embodiment, like the substrate 710 of FIG. 7, the substrate 810 has a generally rectangular shape and extends underneath the pair of host devices 830, but does not extend underneath the first HBM devices 840a. The first HBM devices 840a can be carried by the connection layer (not shown), and the second HBM devices can be positioned along the edges of the substrate 810.

Unlike the substrate 710, however, the substrate 810 includes one or more apertures 814. The apertures 814 can be positioned at various places across the substrate 810, such as adjacent to the portion of the substrate 810 beneath the host devices 830, as shown. Each of the apertures 814 can be shaped and sized to receive a dummy die 860. In some embodiments, the dummy dies 860 can be coupled to the connection layer and can have a higher rigidity than the substrate 810. Accordingly, the inclusion of the dummy dies 860 in the apertures 814 can help the SiP device 800 resist warpage and/or provide other mechanical benefits. Additionally or alternatively, in some embodiments, the SiP device 800 can include the dummy dies 860 positioned adjacent to the first HBM devices 840a and/or the second HBM devices. These dummy dies 860 can similarly be coupled to the connection layer and provide mechanical benefits to the SiP device 800.

Referring to FIGS. 2A–8 together, in each of the SiP devices illustrated herein, one or more of the HBM devices are positioned at the same level as the substrate. Accordingly, compared to many existing SiP devices (e.g., the SiP device 100 of FIGS. 1A and 1B), SiP devices configured in accordance with embodiments of the present technology can include a greater number of HBM devices to be included in a SiP device (and thus a higher memory density) without exceeding the height cap H1, while occupying the same amount of or less real estate, and while a larger or the same effective core area for the host devices. Moreover, SiP devices configured in accordance with embodiments of the present technology can be manufactured and packaged using existing assembly equipment and technology. Furthermore, SiP devices configured in accordance with embodiments of the present technology are compatible with existing systems and do not require adapters and/or the like.

Also, it is appreciated that the illustrated embodiments herein are merely examples, and that the scope of the present technology is not so limited. For example, while each figure illustrates a certain number of host devices and/or HBM devices included in the illustrated SiP device, other embodiments can include a different number of host devices and/or HBM devices while retaining the features discussed with reference to that figure. Moreover, it is appreciated that features illustrated in different figures can be combined in any suitable manner. For example, a SiP device configured in accordance with embodiments of the present technology can include HBM devices without base dies, as illustrated in FIG. 5, and positioned along the periphery of the substrate, as illustrated in FIGS. 6A–8. As another example, a SiP device configured in accordance with embodiments of the present technology can include a substrate with recesses, as illustrated in FIG. 4, positioned along the periphery of the substrate, as illustrated in FIGS. 6A–8.

### Select Embodiments of Process Flows for Packaging SiP Devices

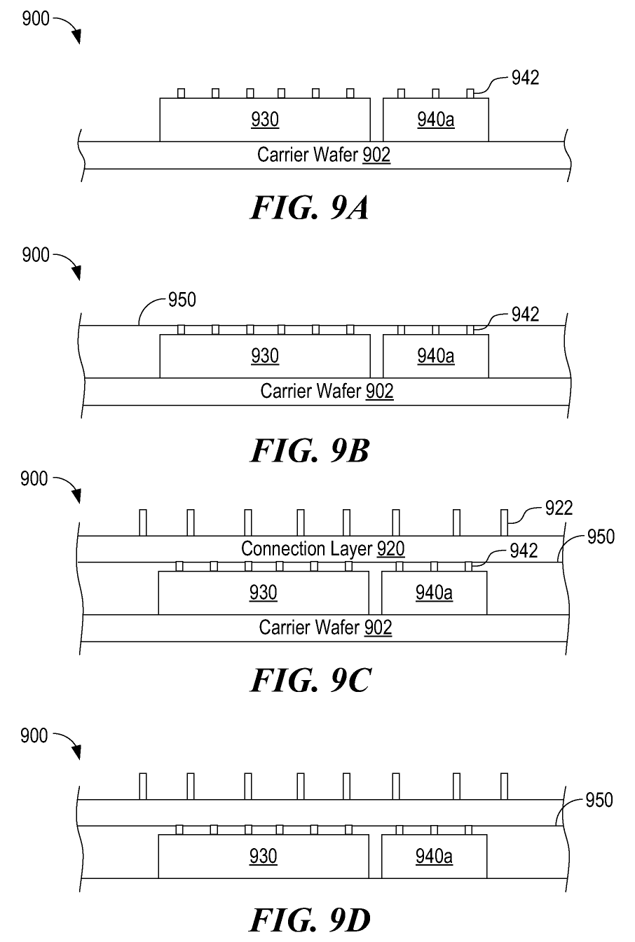

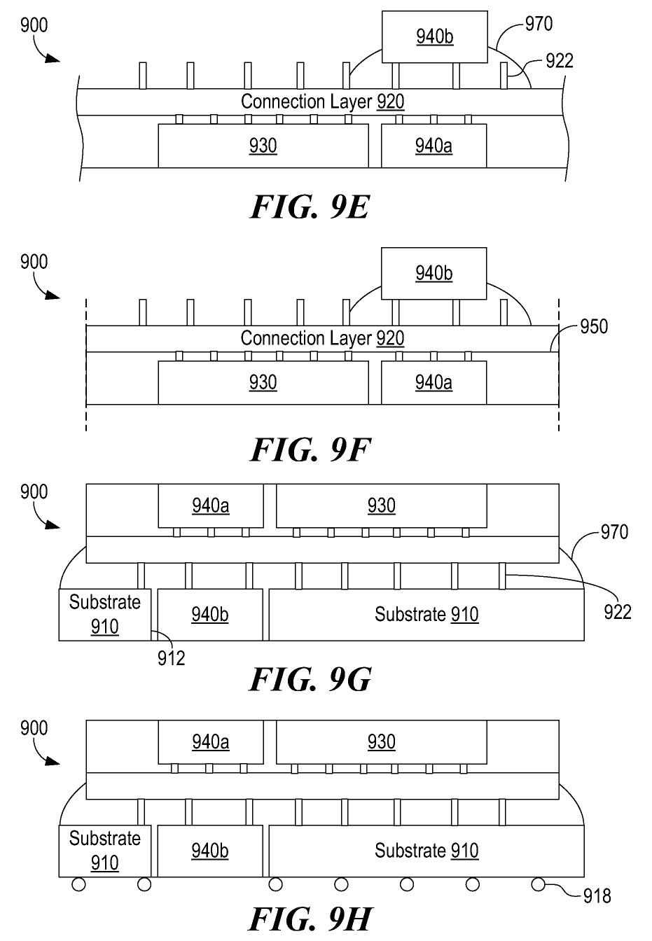

FIGS. 9A–9H illustrate a process flow for packaging a SiP device 900 in accordance with embodiments of the present technology. It is appreciated that while the SiP device 900 is illustrated as a specific embodiment of the present technology, the process flow described herein can be applied to packaging various embodiments of SiP devices. Also, while the process flow is illustrated and described herein in a particular order, variations of the process flow (e.g., different orders, omitting certain steps, performing additional steps) are within the scope of the present technology.

Referring first to FIG. 9A, a host device 930 and one or more first HBM devices 940a can be temporarily bonded to a carrier wafer 902 (e.g., via adhesives). In some embodiments, interconnect structures 942 are formed on the sides of the host device 930 and the first HBM devices 940a opposite the carrier wafer 902.

Referring next to FIG. 9B, an encapsulant 950 (or other suitable mold) can be applied to at least partially encapsulate the host device 930, the first HBM devices 940a, and the interconnect structures 942 over the carrier wafer 902. The interconnect structures 942 can remain exposed at the top surface for further electrical connectivity. Subsequently, the top surface of the encapsulant 950 can be planarized for applying additional layers thereon.

Referring next to FIG. 9C, a connection layer 920 can be formed on the encapsulant 950 and in electrical communication with the interconnect structures 942. The connection layer 920 can be a redistribution layer (RDL), a silicon interposer, and/or the like. Subsequently, interconnect structures 922 can be formed on the connection layer 920. The interconnect structures 922 can be solder structures (e.g., solder balls), metal-metal bonds, bumps, micro bumps, and/or any other suitable conductive structures.

Referring next to FIG. 9D, the carrier wafer 902 can be detached from the host device 930, the first HBM devices 940a, and the encapsulant 950. The carrier wafer 902 can be detached via various known debonding techniques.

Referring next to FIG. 9E, one or more second HBM devices 940b can be coupled to the interconnection structures 922. In particular, the second HBM devices 940b can be positioned to be vertically aligned with corresponding ones of the first HBM devices 940a, thus forming pairs. In some embodiments, the first HBM devices 940a and the second HBM devices 940b each includes a base die, and each pair of a first HBM device 940a and a second HBM device 940b are in a F2F arrangement such that their base dies face one another. In some embodiments, the second HBM devices 940b do not include base dies. In some embodiments, a suitable underfill material 970 can be applied at least partially around the second HBM devices 940b and the interconnect structures 922 coupled thereto to provide additional mechanical support.

Referring next to FIG. 9F, the SiP device 900 can be singulated using, e.g., known die singulation techniques. In particular, the encapsulant 950 and the connection layer 920 can be cut to desired dimensions.

Referring next to FIG. 9G, the SiP device 900 packaged thus far can be flipped upside down, and a substrate 910 can be coupled to the interconnect structures 922. In the illustrated embodiment, the substrate 910 includes one or more apertures 912 shaped and sized to receive the second HBM devices 940b. Accordingly, the substrate 910 can be positioned and coupled such that the second HBM devices 940b properly fit in the pre-formed apertures 912. It is appreciated in other embodiments, the substrate 910 can additionally or alternatively include recesses, notches, or none of the above, as discussed above with reference to FIGS. 4 and 6A–8. In some embodiments, more of the underfill material 970 can be applied to the gap between the substrate 910, the connection layer 920, the interconnect structures 922, and the second HBM devices 940b

Referring next to FIG. 9H, interconnect structures 918 can be applied to the side of the substrate 910 opposite the interconnect structures 922. The interconnect structures 918 can enable the transmission of power and/or signals between the SiP device 900 and other components (not shown).

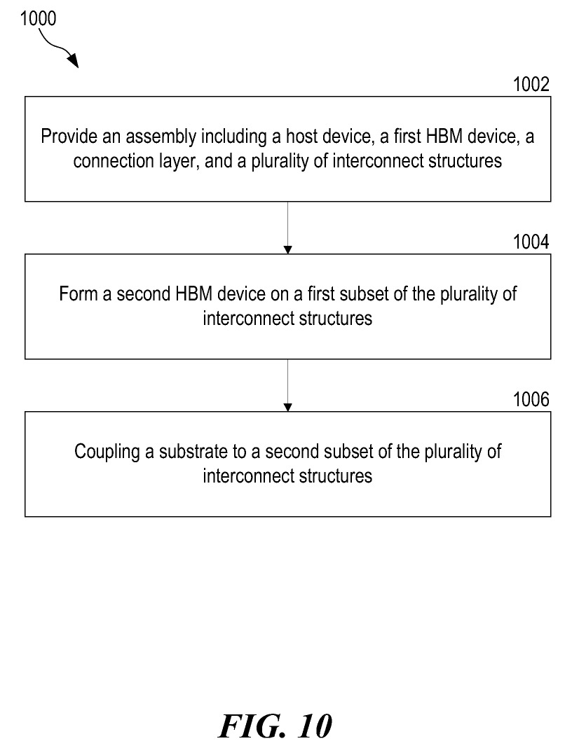

FIG. 10 is a flowchart illustrating a method 1000 for packaging a SiP device in accordance with embodiments of the present technology. While the steps of the method 1000 are described below in a particular order, one or more of the steps can be performed in a different order or omitted, and the method 1000 can include additional and/or alternative steps. Additionally, although the method 1000 may be described below with reference to the embodiments of the present technology described herein, the method 1000 can be performed with other embodiments of the present technology.

The method 1000 begins at block 1002 by providing an assembly including a host device (e.g., the host device 230), a first HBM device (e.g., the first HBM device 240a), a connection layer (e.g., the connection layer 220), and a plurality of interconnect structures (e.g., the interconnect structures 222). The connection layer can have a first side coupled to each of the host device and the first HBM device. The plurality of interconnect structures can be coupled to a second side of the connection layer. In some embodiments, the assembly is provided according to the process flow illustrated in FIGS. 9A–9D.

At block 1004, the method 1000 continues by forming a second HBM device on a first subset of the plurality of interconnect structures. The connection layer and the first subset of the plurality of interconnect structures can electrically couple the second HBM device to the host device and/or the first HBM device. Forming the second HBM device can comprise vertically aligning the second HBM device with the first HBM device. In some embodiments, the second HBM device is formed according to the process flow illustrated in FIG. 9E.

At block 1006, the method 1000 continues by coupling a substrate to a second subset of the plurality of interconnect structures, wherein the substrate is positioned at a same level as the second HBM device. Coupling the substrate can comprise positioning the substrate such that an aperture, a recess, or notch of the substrate aligns with and receives the second HBM device. Coupling the substrate can additionally or alternatively comprise positioning the substrate such that the second HBM device is positioned adjacent to a periphery of the substrate. In some embodiments, the substrate is coupled according to the process flow illustrated in FIG. 9G.

In some embodiments, the method 1000 can include additional steps, such as the process flow illustrated in FIGS. 9F and/or 9H. For example, the method 1000 can further include applying an underfill material between the substrate, the connection layer, and the second HBM device.

### CONCLUSION

It will be apparent to those having skill in the art that changes may be made to the details of the above-described embodiments without departing from the underlying principles of the present disclosure. In some cases, well known structures and functions have not been shown or described in detail to avoid unnecessarily obscuring the description of the embodiments of the present technology. Although steps of methods may be presented herein in a particular order, alternative embodiments may perform the steps in a different order. Similarly, certain aspects of the present technology disclosed in the context of particular embodiments can be combined or eliminated in other embodiments. Furthermore, while advantages associated with certain embodiments of the present technology may have been disclosed in the context of those embodiments, other embodiments can also exhibit such advantages, and not all embodiments need necessarily exhibit such advantages or other advantages disclosed herein to fall within the scope of the technology. Accordingly, the disclosure and associated technology can encompass other embodiments not expressly shown or described herein, and the invention is not limited except as by the appended claims.

Where the context permits, singular or plural terms may also include the plural or singular term, respectively. For example, throughout this disclosure, the singular terms “a,” “an,” and “the” include plural referents unless the context clearly indicates otherwise. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, a step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

Reference herein to “one embodiment,” “an embodiment,” “some embodiments” or similar formulations means that a particular feature, structure, operation, or characteristic described in connection with the embodiment can be included in at least one embodiment of the present technology. Thus, the appearances of such phrases or formulations herein are not necessarily all referring to the same embodiment. Furthermore, various particular features, structures, operations, or characteristics may be combined in any suitable manner in one or more embodiments.

Unless otherwise indicated, all numbers expressing numerical values used in the specification and claims, are to be understood as being modified in all instances by the term “about.” Accordingly, unless indicated to the contrary, the numerical parameters set forth in the specification and attached claims are approximations that may vary depending upon the desired properties sought to be obtained by the present technology. At the very least, and not as an attempt to limit the application of the doctrine of equivalents to the scope of the claims, each numerical parameter should at least be construed in light of the number of reported significant digits and by applying ordinary rounding techniques. The terms “about,” “approximately,” and “substantially” as used herein shall be interpreted to mean within ±10% of the stated value. Additionally, all ranges disclosed herein are to be understood to encompass the endpoints, and any and all subranges subsumed therein. For example, a range of “1 to 10” includes any and all subranges between (and including) the minimum value of 1 and the maximum value of 10 (e.g., any and all subranges having a minimum value of equal to or greater than 1 and a maximum value of equal to or less than 10, such as 5.5 to 10).

The disclosure set forth above is not to be interpreted as reflecting an intention that any claim or example requires more features than those expressly recited in that claim or example. Rather, as the preceding examples and the following claims reflect, inventive aspects lie in a combination of fewer than all features of any single foregoing disclosed embodiment. Thus, the preceding examples and the following claims are hereby expressly incorporated into the Detailed Description, with each claim standing on its own as a separate embodiment. This disclosure includes all permutations of the independent claims with their dependent claims.

What is claimed is:

1. A system-in-package (SiP) device, comprising:
a substrate positioned at a first level;
a connection layer carried by the substrate;
a host device carried by the connection layer and positioned at a second level different from the first level;
a first high-bandwidth memory (HBM) device carried by the connection layer and positioned at the second level; and
a second HBM device coupled to the connection layer and positioned at the first level.

2. The SiP device of claim 1, wherein the substrate includes an aperture shaped and sized to receive the second HBM device, and wherein the second HBM device is positioned in the aperture.

3. The SiP device of claim 1, wherein the substrate includes a recess shaped and sized to receive the second HBM device, and wherein the second HBM device is positioned in the recess.

4. The SiP device of claim 1, wherein the substrate includes a notch along a periphery of the substrate, wherein the notch is shaped and sized to receive the second HBM device, and wherein the second HBM device is positioned in the notch.

5. The SiP device of claim 1, wherein the substrate does not include an aperture, a recess, or a notch, and wherein the second HBM device is positioned adjacent to a periphery of the substrate.

6. The SiP device of claim 1, wherein the substrate includes an aperture adjacent to a portion of the substrate positioned beneath the host device, and wherein the SiP device further includes a dummy die positioned in the aperture.

7. The SiP device of claim 1, wherein the first HBM device includes a first base die, wherein the second HBM device includes a second base die, and wherein the first HBM device and the second HBM device are in a face-to-face (F2F) arrangement such that the first base die and the second base die face one another.

8. The SiP device of claim 1, wherein the first HBM device includes a first base die having a first physical layer (PHY) area, wherein the second HBM device includes a second base die having a second PHY area, and wherein the host device includes a host PHY area electrically coupled to both the first PHY area and the second PHY area.

9. The SiP device of claim 1, wherein the second HBM device does not include a base die, and wherein the first HBM device includes a base die configured to perform control operations for both the first HBM device and the second HBM device.

10. The SiP device of claim 1, wherein the first HBM device and the second HBM device are vertically aligned.

11. The SiP device of claim 1, wherein a portion of a height of the SiP device above the connection layer is no more than 775 µm.

12. The SiP device of claim 1, further comprising underfill material between the substrate, the connection layer, and the second HBM device.

13. A method for packaging a system-in-package (SiP) device, the method comprising:
providing an assembly including a host device, a first high-bandwidth memory (HBM) device, a connection layer having a first side coupled to each of the host device and the first HBM device, and a plurality of interconnect structures coupled to a second side of the connection layer;
forming a second HBM device on a first subset of the plurality of interconnect structures; and
coupling a substrate to a second subset of the plurality of interconnect structures, wherein the substrate is positioned at a same level as the second HBM device.

14. The method of claim 13, wherein coupling the substrate comprises positioning the substrate such that an aperture, a recess, or notch of the substrate aligns with and receives the second HBM device.

15. The method of claim 13, wherein coupling the substrate comprises positioning the substrate such that the second HBM device is positioned adjacent to a periphery of the substrate.

16. The method of claim 13, wherein forming the second HBM device comprises vertically aligning the second HBM device with the first HBM device.

17. The method of claim 13, further comprising applying an underfill material between the substrate, the connection layer, and the second HBM device.

18. A system-in-package (SiP) device, comprising:
a substrate;
a connection layer having a first side and a second side opposite the first side, wherein the second side of the connection layer is coupled to the substrate;
a host device coupled to the first side of the connection layer;
a first high-bandwidth memory (HBM) device coupled to the first side of the connection layer; and
a second HBM device coupled to the second side of the connection layer.

19. The SiP device of claim 18, wherein the second HBM device is positioned at a same level as the substrate.

20. The SiP device of claim 18, wherein the first HBM device includes a first base die having a first physical layer (PHY) area, wherein the second HBM device includes a second base die having a second PHY area, and wherein the host device includes a host PHY area electrically coupled to both the first PHY area and the second PHY area.
